(19) United States
(12) Patent Application Publication
(10) Pub. No.: US 2024/0124362 A1
(43) Pub. Date: Apr. 18, 2024

(54) LEAD-FREE PIEZOELECTRIC CERAMIC COMPOSITION AND METHOD FOR MANUFACTURING LEAD-FREE PIEZOELECTRIC CERAMIC

(71) Applicant: IUCF-HYU (INDUSTRY-UNIVERSITY COOPERATION FOUNDATION HANYANG UNIVERSITY), Seoul (KR)

(72) Inventors: Tae-Hyun SUNG, Seoul (KR); Kyung Bum KIM, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/277,308

(22) PCT Filed: Feb. 15, 2022
(86) PCT No.: PCT/KR2022/002209

§ 371 Date: Aug. 15, 2023

(51) Int. Cl. C04B 35/468; C04B 35/64

(52) U.S. Cl. CPC C04B 35/4682; C04B 35/64; C04B 2235/3249; C04B 2235/3281; C04B 2235/6567; H04R 17/00

(57) ABSTRACT

Disclosed are a BCTZ-based lead-free piezoelectric ceramic composition and a method of preparing a BCTZ-based lead-free piezoelectric ceramic which provide high piezoelectric properties and speaker characteristics. The method of preparing a lead-free piezoelectric ceramic includes preparing a mixture in which copper oxide is added to a BCTZ-based base material and sintering the mixture at a temperature of 1300° C. to 1600° C. for 1 to 5 hours, wherein a weight ratio of the copper oxide in the mixture is 0.6 wt %.

### TECHNICAL FIELD

The present disclosure relates to a lead-free piezoelectric ceramic composition and a method of preparing a lead-free piezoelectric ceramic, and more specifically, to a lead-free piezoelectric ceramic composition and a method of preparing a lead-free piezoelectric ceramic having high speaker characteristics in a high frequency band.

### BACKGROUND ART

Piezoelectric ceramic materials exhibit a piezoelectric phenomenon and have been applied to various fields such as transformers for liquid crystal display (LCD) backlights, ultra-precision actuators, ultrasonic motors, sensors, and energy harvesting systems, and many studies have been conducted over the past several decades.

Currently, mainstream piezoelectric ceramic materials are Pb(Zr,Ti)O₃ (PZT)-based materials, which are lead-based perovskite-structured ferroelectric compounds. Since the PZT-based materials cause a problem of fatal poisoning in the human body, volatilization of lead causes environmental pollution, and thus interest in the development of eco-friendly piezoelectric ceramic materials is gradually increasing in order to fundamentally solve these problems.

Accordingly, many studies have been conducted to improve the piezoelectric properties of (BiNa)TiO₃ (BNT)-based and (NaK)NbO₅ (NKN)-based materials which are general lead-free piezoelectric ceramic materials. However, the piezoelectric properties thereof still have low values (d₃₃ is 100 to 200 pC/N) compared to PZT-based piezoelectric ceramics.

(Ba,Ca)(Ti,Zr)O₃ (BCTZ)-based lead-free piezoelectric ceramic materials newly developed by Liu and Ren have perovskite structures, and studies on a BCTZ-based lead-free piezoelectric ceramic exhibiting a relatively high electromechanical conversion constant (k p) and piezoelectric charge constant (d₃₃) have been actively conducted recently.

### DISCLOSURE

### Technical Problem

Accordingly, the present disclosure is directed to providing a (Ba,Ca)(Ti,Zr)O₃ (BCTZ)-based lead-free piezoelectric ceramic composition with improved piezoelectric properties and a method of preparing a BCTZ-based lead-free piezoelectric ceramic.

In particular, the present disclosure is also directed to providing a lead-free piezoelectric ceramic composition and a method of preparing a lead-free piezoelectric ceramic for a speaker capable of providing ultra-high sound quality in a high frequency band.

### Technical Solution

One aspect of the present disclosure provides a method of preparing a lead-free piezoelectric ceramic includes preparing a mixture in which copper oxide is added to a BCTZ-based base material and sintering the mixture at a temperature of 1300° C. to 1600° C. for 1 to 5 hours, wherein a weight ratio of the copper oxide in the mixture is 0.6 wt %.

In addition, another aspect of the present disclosure provides a lead-free piezoelectric ceramic composition includes a BCTZ-based base material and copper oxide (CuO), wherein a weight ratio of the copper oxide is 0.6 wt % in the lead-free piezoelectric ceramic composition.

### Advantageous Effects

According to one embodiment of the present disclosure, the piezoelectric properties of a BCTZ-based lead-free piezoelectric ceramic composition can be improved.

In addition, according to one embodiment of the present disclosure, a speaker providing a high gain in a high frequency band can be provided.

### DESCRIPTION OF DRAWINGS

FIG. 1 is a set of field emission scanning electron microscope (FE-SEM) images of a lead-free piezoelectric ceramic according to sintering temperatures.

FIG. 2 is a set of X-ray diffraction (XRD) graphs of the lead-free piezoelectric ceramic according to sintering temperatures.

### MODES OF THE INVENTION

While the present disclosure may be modified in various ways and have various alternative forms, specific embodiments thereof will be described in detail below. However, there is no intent to limit the present disclosure to the specific embodiments, and it should be understood that the present disclosure covers all modifications, equivalents, and alternatives falling within the range of the spirit and scope of the present disclosure. When the present disclosure is described with reference to the accompanying drawings, like numbers refer to like elements.

Hereinafter, embodiments according to the present disclosure will be described in detail.

Lead-Free Piezoelectric Ceramic Composition

A lead-free piezoelectric ceramic composition according to the present disclosure is a BCTZ-based lead-free piezoelectric ceramic composition capable of providing improved piezoelectric properties and a high gain in a high frequency band and includes a BCTZ-based base material and copper oxide (CuO).

The lead-free piezoelectric ceramic composition according to one embodiment of the present disclosure is a composition in which the copper oxide is added as an auxiliary material to (Ba_{0.85}Ca_{0.15})(Ti_{0.9}Zr_{0.1})O₃, which is a BCTZ-based base material. The copper oxide may be added so that a weight ratio of the copper oxide is 0.6 wt % in the lead-free piezoelectric ceramic composition.

Since the lead-free piezoelectric ceramic composition according to one embodiment of the present disclosure exhibits speaker characteristics that provide a high gain in a high frequency band of 10 kHz, the lead-free piezoelectric ceramic composition can be used for speakers, especially earphones, and the like, which provide ultra-high sound quality in the high frequency band.

Parts which provide high gain at a high frequency are used in speakers, earphones, and the like, however, most parts are formed of a lead-containing piezoelectric ceramic composition. According to one embodiment of the present disclosure, an eco-friendly lead-free piezoelectric ceramic composition, which provides excellent speaker properties even without lead, can be provided.

Piezoelectric properties and speaker characteristics of the lead-free piezoelectric ceramic composition according to one embodiment of the present disclosure will be described in detail below.

Method of Preparing Lead-Free Piezoelectric Ceramic

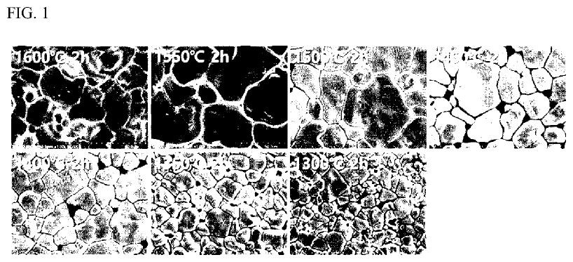

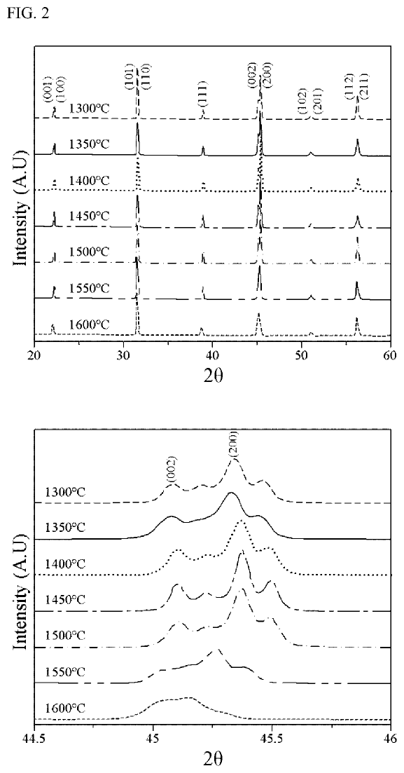

FIGS. 1 and 2 are views for describing a method of preparing a lead-free piezoelectric ceramic according to one embodiment of the present disclosure. FIG. 1 is a set of field emission scanning electron microscope (FE-SEM) images of a lead-free piezoelectric ceramic according to sintering temperatures, and FIG. 2 is a set of X-ray diffraction (XRD) graphs of the lead-free piezoelectric ceramic according to the sintering temperatures. In FIG. 2, an x-axis represents 2θ, and a y-axis represents intensity.

The method of preparing a lead-free piezoelectric ceramic according to the present disclosure includes preparing a mixture in which copper oxide is added to a BCTZ-based base material and sintering the mixture.

As one embodiment, (Ba_{0.85}Ca_{0.15})(Ti_{0.9}Zr_{0.1})O₃ is used as a BCTZ-based base material, and a mixture, to which copper oxide is added so that a weight ratio of the copper oxide is 0.6 wt %, may be prepared. Then, barium carbonate (BaCO₃) and calcium carbonate (CaCO₃) at a molar ratio of 0.85:0.15 and titanium dioxide (TiO₂) and zirconium dioxide (ZrO₂) at a molar ratio of 0.9:0.1 may be mixed and grinded to prepare (Ba_{0.85}Ca_{0.15}) (Ti_{0.9}Zr_{0.1})O₃.

As the mixture is sintered at a sintering temperature of 1300° C. to 1600° C. for 1 to 5 hours, a lead-free piezoelectric ceramic may be prepared, and when the mixture is sintered at a temperature of 1550° C. for 2 hours, a lead-free piezoelectric ceramic exhibiting superior piezoelectric properties and speaker characteristics may be manufactured.

FIGS. 1 and 2 and Table 1 shows properties of a lead-free piezoelectric ceramic prepared by sintering a BCTZ-based lead-free piezoelectric ceramic composition, in which the weight ratio of the copper oxide is 0.6 wt %, at a temperature controlled in 50° C. increments in the range of 1300° C. to 1600° C. In this case, a sintering time was 2 hours, and 1259.62 g of BaCO₃, 112.47 g of CaCO₃, 538.58 g of TiO₂, 92.3112 g of ZrO₂, and 6 g of CuO were used. In addition, the seven images of FIG. 1 are the FE-SEM images at sintering temperatures of 1600° C., 1550° C., 1500° C., 1450° C., 1400° C., 1350° C., and 1300° C. in order from the first image at an upper left side to the last image at a lower right side of FIG. 1.

Referring to FIG. 1, as the sintering temperature increases from 1300° C. to 1550° C., a grain size of the lead-free piezoelectric ceramic increases, however, when the sintering is performed at 1600° C., the grain size decreases, and a phenomenon in which a surface of the lead-free piezoelectric ceramic was melted was observed. In addition, referring to FIG. 2, as the sintering temperature increases from 1300° C. to 1550° C., a tetragonal phase appears more clearly, however, when the sintering is performed at 1600° C., a phenomenon in which the tetragonal phase disappears was observed.

Accordingly, it can be predicted that, as the sintering temperature increases from 1300° C. to 1550° C., the piezoelectric properties are improved, and when the sintering is performed at 1600° C., the piezoelectric properties are degraded, and it can be predicted that the speaker characteristics also improve with the improvement of the piezoelectric properties. In addition, the prediction results are consistent with the piezoelectric properties shown in Table 1.

Table 1 shows the piezoelectric properties and the speaker characteristics of the lead-free piezoelectric ceramic. For measurement of the piezoelectric properties and the speaker characteristics, a lead-free piezoelectric ceramic sample prepared by cutting a sheet, on which the lead-free piezoelectric ceramic composition according to one embodiment of the present disclosure was laminated, into a size of 1 cm 2, and sintering the cut sheet for 2 hours and then baking silver (Ag) electrodes at 650° C., was used. A voltage of 8 Vp-p at a frequency of 10 kHz was applied to the lead-free piezoelectric ceramic sample to measure the speaker characteristics.

TABLE 1

| Sintering | Sintering | | | | | | | |
|---|---|---|---|---|---|---|---|---|
| temperature | time | d₃₃ | Capacitance | | | g₃₃ | d₃₃g₃₃ | dB |
| (° C.) | (hour) | (10⁻¹² m/V) | (pF) | kₚ | Qₘ | (10⁻³ m V/N) | (10⁻¹⁵ m²/N) | (10 kHz) |
| 1600 | 2 | 425 | 1769 | 0.225 | 51 | 57.20 | 24.310 | 58 |
| 1550 | 2 | 800 | 2870 | 0.281 | 78 | 96.23 | 53.094 | 88 |
| 1500 | 2 | 660 | 3233 | 0.436 | 87 | 30 | 19.864 | 75 |
| 1450 | 2 | 650 | 3544 | 0.369 | 739 | 27 | 17.574 | 67 |
| 1400 | 2 | 600 | 3254 | 0.327 | 130 | 27 | 16.308 | 62 |
| 1350 | 2 | 550 | 3049 | 0.312 | 176 | 27 | 14.625 | 57 |
| 1300 | 2 | 450 | 2508 | 0.434 | 23 | 26 | 11.902 | 55 |

Parameters representing the piezoelectric properties are a piezoelectric voltage constant (g₃₃), a piezoelectric charge constant (d₃₃), and a piezoelectric conversion constant (d₃₃g₃₃), and a higher value represents a higher piezoelectric property. In addition, in the speaker characteristics, a higher gain value indicates a higher speaker characteristic.

Referring to Table 1, it can be seen that the piezoelectric voltage constant, the piezoelectric charge constant, and the piezoelectric conversion constant increase as the sintering temperature increases from 1300° C. and have highest values at the sintering temperature of 1550° C. That is, the best piezoelectric properties are exhibited when the sintering is performed at the sintering temperature of 1550° C. for 2 hours. In addition, it can be seen that all the piezoelectric voltage constant, the piezoelectric charge constant, and the piezoelectric conversion constant rapidly decrease at 1600° C. which is a sintering temperature higher than 1550° C.

In addition, it can be seen that a gain value (db) representing the speaker characteristic also increases as the sintering temperature increases from 1300° C. and exhibits the highest value at the sintering temperature of 1550° C. In addition, it can be seen that the gain value rapidly decreases at 1600° C. which is a sintering temperature higher than 1550° C.

Meanwhile, Table 2 shows the characteristics of the lead-free piezoelectric ceramic sintered at the sintering temperature of 1500° C. for 1 to 5 hours. When the sintering is performed at 1500° C., it can be seen that the best piezoelectric properties are exhibited when the sintering is performed for 3 hours, and when the sintering is performed for greater or smaller than 3 hours, the piezoelectric properties are degraded.

TABLE 2

| Sintering | Sintering | | | | | | |
|---|---|---|---|---|---|---|---|
| temperature | time | d₃₃ | Capacitance | | | g₃₃ | d₃₃ · g₃₃ |
| (° C.) | (hour) | (10⁻¹² m/V) | (pF) | kₚ | Qₘ | (10⁻³ m · V/N) | (10⁻¹⁵ m²/N) |
| 1500 | 1 | 640 | 3636 | 0.477 | 143 | 26 | 16.606 |
| 1500 | 2 | 660 | 3233 | 0.436 | 87 | 30 | 19.864 |
| 1500 | 3 | 750 | 3664 | 0.480 | 94 | 30 | 22.630 |
| 1500 | 4 | 650 | 3520 | 0.461 | 127 | 27 | 17.693 |
| 1500 | 5 | 600 | 3476 | 0.433 | 108 | 25 | 15.267 |

While the present disclosure has been described with reference to specific details such as detailed components, these are provided only to facilitate overall understanding of the disclosure, and the disclosure is not limited thereto and may be variously modified and changed by those skilled in the art. Therefore, the spirit and scope of the disclosure are defined not by the detailed description of the disclosure but by the appended claims, and encompasses all modifications and equivalents that fall within the scope of the appended claims.

1. A method of preparing a lead-free piezoelectric ceramic, comprising:
preparing a mixture in which copper oxide is added to a BCTZ-based base material; and
sintering the mixture at a temperature of 1300° C. to 1600° C. for 1 to 5 hours,
wherein a weight ratio of the copper oxide in the mixture is 0.6 wt %.

2. The method of claim 1, wherein the sintering of the mixture includes sintering the mixture at a temperature of 1550° C. for 2 hours.

3. The method of claim 1, wherein the sintering of the mixture includes sintering the mixture at a temperature of 1500° C. for 3 hours.

4. The method of claim 1, wherein the BCTZ-based base material includes (Ba_{0.85}Ca_{0.15})(Ti0.9Zr_{0.1})O₃.

5. The method of claim 1, wherein the lead-free piezoelectric ceramic is a lead-free piezoelectric ceramic for a speaker.

6. A lead-free piezoelectric ceramic composition comprising:
BCTZ-based base material; and
copper oxide (CuO),
wherein a weight ratio of the copper oxide is 0.6 wt % in the lead-free piezoelectric ceramic composition.

7. The lead-free piezoelectric ceramic composition of claim 6, wherein the BCTZ-based base material includes (Ba_{0.85}Ca_{0.15})(Ti_{0.9}Zr_{0.1})O₃.

8. The lead-free piezoelectric ceramic composition of claim 6, which is a lead-free piezoelectric ceramic composition for a speaker.
